(19) United States
(12) Patent Application Publication
(10) Pub. No.: US 2025/0234786 A1
(43) Pub. Date: Jul. 17, 2025

(54) METALLIZATION AND SUPPORT COMPRISING A METALLIZATION

(71) Applicant: Kistler Holding AG, Winterthur (CH)

(72) Inventors: Giovanni Mastrogiacomo, Zürich (CH); Hans Beat Märki, Kollbrunn (CH); Urs Pfister, Winterthur (CH)

(21) Appl. No.: 18/983,940

(22) Filed: Dec. 17, 2024

(30) Foreign Application Priority Data
Dec. 18, 2023 (EP) 23217418.5

(51) Int. Cl. H10N 30/87

(52) U.S. Cl. CPC H10N 30/872

(57) ABSTRACT

A system includes a support and at least one metallization that defines at least a first layer and a second layer. The support defines a support surface on which the first layer is arranged between the support surface and the second layer, which is made of at least 90% by weight of a precious metal. The first layer is made of transition metals and/or metals and/or semi-metals and has an ultrasonic damping effect.

### FIELD OF THE INVENTION

The invention relates to a metallization comprising a first layer and a second layer, and to a support, for example an oxide ceramic, comprising a metallization with improved resistance.

### BACKGROUND OF THE INVENTION

Oxide ceramics are used as supports, also known as substrates, in a variety of applications, for example as insulators, substrates in printed circuit boards or as measuring element.

In technical applications, supports are often provided with a metallization. It is frequently provided for conducting electrical charges. Thus, a metallization may be provided in the form of a conductor track, an electrode or a protection against static charging of otherwise electrically insulating surfaces. For these purposes, the metallization covers at least a partial area of an oxide ceramic surface.

Generally, oxide ceramics such as quartz, gallium phosphate or langasite are metallized by using layer structures of refractory metals and precious metals. The refractory metal layer serves as an adhesion promoting layer since it provides good adhesion to the oxide ceramics due to its high oxygen affinity. The precious metal layer on the other hand is used for good electrical conductivity and/or bondability of the layer.

With reference to the periodic table, refractory metals are understood to mean elements of the 4th subgroup (titanium, zirconium and hafnium), the 5th subgroup (vanadium, niobium and tantalum), or the 6th subgroup (chromium, molybdenum and tungsten). For the purposes of this application, precious metals are understood to mean gold, platinum, iridium, palladium, osmium, ruthenium, rhodium and silver.

Bondability exists when it is possible for a conductor, for example a bonding wire made of gold or aluminum, to achieve a connection between materials, also referred to as a bond, between a layer and the conductor by means of common bonding technologies such as wire bonding, also known as ultrasonic bonding or thermosonic bonding.

It is well known that materials with a high modulus of elasticity, such as for example refractory metals, have only poor damping properties against mechanical vibrations. This is a disadvantage because the ultrasound used in wire bonding is transmitted well to the support. The resulting mechanical stress caused by the mechanical vibrations due to the ultrasound often leads to spalling and/or cracking in the substrate, in particular in an oxide ceramic substrate, which in turn reduce the adhesive strength of the connection between materials, also referred to as bonding or bond herein. Cracking and/or spalling are generally referred to as damage caused by the vibration-induced mechanical stresses, also known as mechanical load.

Ultrasound is generally understood to mean sound or sound waves having a frequency between 20 KHz and 1 GHz. Sound waves are mechanical vibrations.

Particularly when using oxide ceramics as supports that have piezoelectric properties and are used as measuring element in transducers exposed to mechanical stress, spalling and/or cracking within the support in the vicinity of or at the position of a bond is not acceptable. This is because mechanical stress, for example an acceleration of the transducer, may lead to damage of the bond.

It is known from EP2013597A1, which corresponds to applicant's commonly owned US Patent Application Publication No. 2009-217768, which is hereby incorporated herein in its entirety for all purposes by this reference, and EP2029988A2, which corresponds to applicant's commonly owned US Patent Application Publication No. 2009-235762, which is hereby incorporated herein in its entirety for all purposes by this reference, that piezoelectric measuring elements often comprise a metallization in the form of an electrically conductive layer. Platinum is sometimes used as an electrically conductive layer for mechanically protecting the piezoelectric material which is often brittle and is often fabricated from a single crystal. As a precious metal, platinum also has a good chemical resistance to oxidation. A disadvantage is, however, that during bonding of the metallization by means of wire bonding the piezoelectric crystal underneath the metallization may be damaged by the ultrasound-induced mechanical vibrations that are transmitted. This will at first not be directly visible through the metallization since the metallization generally is not damaged but will result in insufficient durability or adhesive strength, respectively, of the bond of the metallization with a conductor because the connection of the metallization to the piezoelectric measuring element is damaged.

### OBJECTS AND SUMMARY OF THE INVENTION

It is an object of the present invention to provide a metallization for a support which reduces the disadvantages mentioned above. Another object of the invention is to reduce mechanical stress for the support due to vibrations, such as e. g. by ultrasound, during wire bonding. It is another object of the invention to provide a system comprising a metallization and a support which can be easily bonded by wire bonding.

The object has been achieved by the features described herein.

The invention relates to a system comprising a support and at least one metallization. The metallization comprises at least a first layer and a second layer. The support defines a support surface. The first layer is arranged between the support surface and the second layer.

A layer, also called a coating, is applied to a support, also called a substrate or base material. The layer covers at least partially a surface of the support, which at least partial surface of the support is called support surface. Thus, the layer has an extension along a first axis and along a second axis wherein the first and second axes extend in parallel to the support surface. Furthermore, the layer has an extension along a third axis that extends perpendicularly to the support surface, which extension along the third axis is referred to as the layer thickness. The layer is fabricated so that it optionally covers a topography of the support surface in an even manner. The layer thickness is determined conventionally by an X-ray fluorescence method according to ISO 3497:2000 of the International Organization for Standardization.

The second layer is made of at least 90% by wt. (90% by weight) of a precious metal. This has the advantage that the layer is resistant to corrosion and thus exhibits high chemical resistance. Precious metals are elements having a highly positive standard potential, also known as the normal potential against a hydrogen electrode. Thus, gold has a standard potential of 1.5 V (volts), silver has a standard potential of 0.8 V, for example. In addition, due to the large proportion of precious metal the second layer exhibits high conductivity and is therefore useful as an electrode for conducting charges and for bonding with a conductor.

The first layer is made of transition metals and/or metals and/or semi-metals. The phrase and/or is to be understood as a non-exclusive disjunction. The first layer has an ultrasonic damping effect. This has the advantage that it reduces the mechanical stress acting onto the support due to vibrations, such as e. g. by ultrasound. In this way, the mechanical stress acting onto the substrate due to mechanical vibrations, such as those occurring during wire bonding, for example, are reduced in an advantageous manner. In particular when a substrate made of oxide ceramic is used, the adhesive strength of a bond between materials between the conductor and the second layer is increased after wire bonding.

In wire bonding, a first end of a conductor, also known as a bonding wire, is pressed onto the second layer by means of a bonding tool. The bonding tool transmits ultrasonic vibrations to the conductor. This results in diffusion processes between the conductor and the second layer creating a bond between materials. However, the ultrasound is not localized to the first layer but propagates through the first layer and the second layer and into the support. The mechanical stress acting onto the support due to the mechanical vibrations caused by the ultrasound are reduced by the second layer that has an ultrasonic damping effect.

Further advantages and aspects of the invention are disclosed in the examples.

### BRIEF DESCRIPTION OF THE DRAWINGS

In the following, the invention will be explained in more detail by way of example referring to the figures in which:

FIG. 1 shows a schematic sectional view of an embodiment of a system wherein the thickness is measured along the Z axis;

FIG. 2 shows a schematic sectional view of an embodiment of a bonded system wherein the thickness is measured along the Z axis;

FIG. 3 shows a schematic sectional view of a further embodiment of a bonded system wherein the thickness is measured along the Z axis;

FIG. 4 schematically shows in perspective a partial view of a further embodiment of a bonded system;

FIG. 5 schematically shows in perspective a partial view of a further embodiment of a bonded system;

FIG. 6 schematically shows in perspective a partial view of a further embodiment of a bonded system.

Throughout the figures, like reference numerals denote like objects or features.

### DETAILED DESCRIPTION OF EXEMPLARY EMBODIMENTS OF THE INVENTION

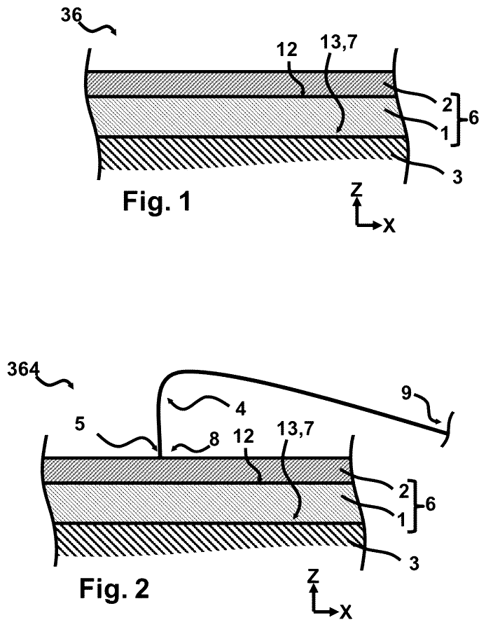

FIG. 1 shows a schematic sectional view of an embodiment of a system 36. The system 36 shown in FIG. 1 comprises a support 3 and a metallization 6. The metallization 6 comprises a first layer 1 and a second layer 2. The support 3 has a support surface 7 that extends along a first axis X and into the image plane in the exemplary FIG. 1. Thus, the system 36 is shown schematically in section perpendicular to the support surface 7. The first layer 1 is arranged between the support surface 7 and the second layer 2.

The dimensions as represented in FIG. 1 to FIG. 6 are not shown to scale, nor can the dimensions of the individual elements be inferred from their size ratios to one another. This is a purely schematic representation.

In all exemplary embodiments shown in the Figures as well as in all further embodiments that are not shown, the second layer 2 is made of at least 90% by weight of a precious metal according to the invention. This has the advantage that the second layer 2 is corrosion-resistant and, thus, has a high chemical resistance. In addition, due to the high proportion of precious metal, the second layer 2 has a high conductivity and is therefore useful as an electrode for conducting charges and for bonding with a conductor 4, as shown by way of example in FIG. 2 to FIG. 6.

The first layer 1 is made of transition metals and/or metals and/or semi-metals in all embodiments according to the invention. Furthermore according to the invention, the first layer 1 has an ultrasonic damping effect. Has an ultrasonic damping effect is understood to mean causes a reduction in the intensity of sound waves transversing the layer having an ultrasonic damping effect. This has the advantage that the mechanical stress acting onto the support 3 caused by vibrations, such as ultrasound, is reduced. In this way, the mechanical stress acting onto the support 3 caused by mechanical vibrations, such as those that occur during wire bonding, is reduced in an advantageous manner. Particularly when using substrates 3 made of oxide ceramic, the adhesive strength of a bond between materials between the conductor 9 and the second layer 2 is increased after wire bonding.

Preferably, the first layer 1 has a mechanical loss coefficient of at least 10⁻⁴. This has the advantage that the system 36 can be bonded by means of wire bonding while the mechanical stress on the support 3 is minimized in such a way that the risk of damaging the support 3 by mechanical vibrations is reduced. The loss factor is understood to mean a factor according to “On the Engineering Properties of Materials”, M. F. Ashby, Acta metall. Vol. 37, No. 5, pp. 1273-1293, (1989) where it is referred to as the loss coefficient or damping coefficient n (lower case Greek letter Eta). In the publication of Ashby, the loss coefficient is equal to the tangent of the loss angle and equal to the ratio between the loss modulus and the storage modulus and therefore is a dimensionless quantity. To a first approximation, the loss factor is inversely related to the Young's modulus of a material such as an alloy or a metal.

The modulus of elasticity of a material always applies to a macroscopic body, in the technical literature also referred to as a macroscopic sample, of the material and is determined according to DIN EN ISO 6892-1 and/or DIN EN ISO 6892-2.

The loss factor is determined as described in “A Comprehensive Report on Ultrasonic Attenuation of Engineering Materials, Including Metals, Ceramics, Polymers, Fiber-Reinforced Composites, Wood, and Rocks”, Kanji Ono, Appl. Sci, 10, 2230 (2020).

Particularly preferably, the first layer 1 has a loss factor of at least 10-4 and furthermore has a layer thickness of between about 500 nm (nanometers) and about 4 μm (micrometers). In FIGS. 1-3, the thickness is measured along the Z axis. It has been shown that with layers having a lower layer thickness it is not possible to achieve adequate mechanical damping of a mechanical vibration that is introduced into the second layer 2 via the first layer 1 to avoid damage to the support 3. On the other hand, a thickness of the first layer 1 that is too high, exceeding 4 μm, leads to a reduction in adhesion promotion due to the residual stresses in the layer 1. This may result in spalling of the layer 1.

In one embodiment, the first layer 1 additionally has a loss factor of at least 10⁻⁴ for mechanical vibrations of a frequency between 20 KHz and 200 kHz, preferably between 40 KHz and 160 KHz. This is advantageous since wire bonding is typically performed in the frequency range between 20 KHz and 200 kHz with most commercial wire bonding devices currently operating at a frequency between 40 KHz and 160 KHz.

In one embodiment, the first layer 1 further has a modulus of elasticity between 60 GPa and 130 GPa; preferably between 80 GPa and 100 GPa. This is advantageous because the layer is elongated to a lesser extent by the stresses generated by the ultrasound. This is known according to Hooke's law since an elongation is equal to a stress divided by the modulus of elasticity. Thus, the risk of damage to the first layer 1 itself due to mechanical stress, for example due to ultrasonic vibrations acting onto the first layer 1, is reduced.

Preferably, the first layer 1 consists of a metal or an alloy with negative standard enthalpy of formation of the oxide of the respective metal or alloy in the temperature range up to 350° C. This has the advantage that the first layer 1 exhibits an increased adhesive strength with respect to the support 3 as compared to a layer made of an alloy with neutral or positive standard enthalpy of formation of the oxide.

A negative standard enthalpy of formation means a negative Gibbs oxidation energy in the Ellingham diagram.

The standard enthalpy of formation is determined for a macroscopic solid of the material of the layer, also known as a macroscopic sample. The determination of the standard enthalpy is done according to DIN 51007-1 using calorimetry and Hess' law of constant heat summation, also known as Hess' law.

Preferably, the first layer 1 is made of bronze. Bronze, also known as bronze alloy, is a copper alloy.

The metallization 6 in its various embodiments is particularly useful for systems 36 where the support 3 is an oxide ceramic. In this case, the support 3 has a modulus of elasticity between 60 GPa and 120 GPa and a coefficient of linear thermal expansion between α=5·10⁻⁶ K⁻¹ and α=20·10⁻⁶ K⁻¹.

The coefficient of linear thermal expansion refers to the coefficient of linear thermal expansion of the material of the layer or the oxide ceramic in the form of the macroscopic solid, also known as the macroscopic sample. The coefficient of linear thermal expansion is determined using a dilatometer in accordance with DIN 51045-1.

The terms coefficient of linear thermal expansion or shortly coefficient of linear expansion and coefficient of thermal expansion are used interchangeably.

Specific oxide ceramics that are particularly susceptible to damage by mechanical stress have a modulus of elasticity between 90 GPa and 110 GPa as well as a coefficient of linear thermal expansion between α=12·10⁻⁶ K⁻¹ and α=18·10⁻⁶ K⁻¹.

Preferably, the first layer 1 is fabricated as an adhesion promoting layer for the support surface 7 and is connected to the support surface 7 by a connection between materials such as a chemical bond. Thus, the first layer 1 has both an ultrasonic damping and an adhesion promoting effect between the second layer 2 and the support 3. This is advantageous because it ensures good bondability of the system with a conductor 9 and durability of this bond of the conductor 9 to the second layer 2. Not only damage to the support 3 is avoided, but also good adhesion of the second layer 2 to the support 3 is achieved.

Preferably, the first layer 1 has a coefficient of linear thermal expansion between α=5·10⁻⁶·K⁻¹ and α=18·10⁻⁶·K⁻¹. This is advantageous as it avoids thermally induced mechanical stresses between the first layer 1 and the substrate 3. Thermally induced mechanical stresses occur in the case of a temperature change between two materials that differ greatly in their coefficients of linear thermal expansion.

Preferably, the second layer 2 has a layer thickness of between 20 nm and 300 nm as measured along the Z axis in FIGS. 1-3. The second layer 2 is useful for bonding with a conductor 9 by means of wire bonding and exhibits good electrical conductivity even at low layer thicknesses of 20 nm. Layer thicknesses above 300 nm should be avoided for cost reasons. Furthermore, in the case of different coefficients of linear thermal expansion mechanical stresses between the first layer 1 and the second layer 2 may increase with increasing layer thickness of the second layer. At layer thicknesses above 300 nm, the second layer 2 exhibits an unfavorable residual stress.

Particularly advantageously, the second layer 2 exhibits high chemical resistance. In this way, the first layer 1 is protected against environmental impacts, for example oxidation by oxygen, in an advantageous manner. Gold or platinum or gold alloys or platinum alloys are particularly useful as the material of the second layer 2.

Particularly advantageously, the second layer 2 exhibits high mechanical resistance. In this way, the first layer 1 is protected against environmental impacts, for example mechanical stresses that cause scratches, in an advantageous manner. To this end, the second layer 2 has a modulus of elasticity of more than 150 GPa. Platinum or platinum alloys are particularly useful as the material for the second layer 2. Platinum and platinum alloys have a high scratch resistance. A Mohs hardness of >3A ensures high scratch resistance. Advantageously the second layer 2 comprises a Mohs hardness >3. Gold has a Mohs hardness of around 2.5 and is therefore not considered as being scratch-resistant. Platinum has a Mohs hardness of 3.4 and is therefore scratch-resistant as are platinum alloys having a Mohs hardness >3.

Particularly preferably, the first layer 1 is a bronze alloy comprising copper, tin and nickel; preferably, the first layer comprises 84.5% by wt. to 87.5% by wt. of copper, 11% by wt. to 13% by wt. of tin, 1.5% by wt. to 2.5% by wt. of nickel. In particular preferably, the first layer 1 contains a maximum of 16% by wt. of elements other than copper, tin and nickel. It has been shown that a bronze alloy of this type has a particularly advantageous e-modulus (modulus of elasticity) of around 90 GPa and a particularly advantageous coefficient of thermal expansion of 17.5·10⁻⁶ K⁻¹ so that the second layer 2 is a particularly suitable adhesion promoter having an ultrasonic damping effect for the specific oxide ceramics that have a modulus of elasticity of between 90 GPa and 110 GPa and a coefficient of linear thermal expansion between α=12·10⁻⁶ K⁻¹ and α=18·10⁻⁶ K⁻¹. Preferably, for achieving good bondability of the system by means of wire bonding, the modulus of elasticity of the first layer 1 differs by not more than 20%, preferably 10%, from the modulus of elasticity of the support 3. It has been shown that for achieving a particularly good resistance of the system 36 to damage of the support 3, the coefficient of thermal expansion of the first layer 1 should not differ by more than 20%, preferably 10%, from the coefficient of thermal expansion of the support 3.

The metallization 6 is particularly useful for a support 3 made of a piezoelectric material, preferably a piezoelectric crystal. Piezoelectric materials are often used in situations where mechanical loads act, for example as an actuator where an electrical voltage is applied to a support surface, or as a piezoelectric measuring element where a mechanical force is exerted onto a support surface 7. Due to its mechanical resistance, the metallization 6 described herein is particularly robust against external mechanical impacts.

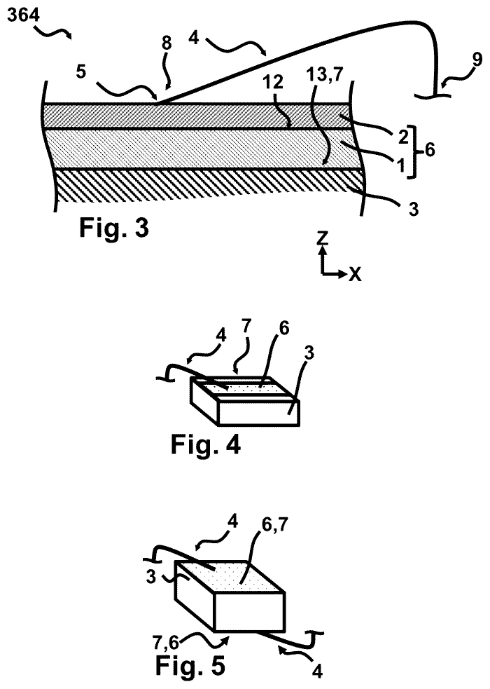

A support 3 comprising a metallization 6 is often bonded with a conductor, as exemplarily shown in FIG. 2 and FIG. 3. A support 3 bonded in this way is referred to as a bonded system 364. A bonded system 364 comprises a support 3, at least one metallization 6 and at least one conductor 4. A conductor 4 comprises a first conductor end 8 and a second conductor end 9. The first conductor end 8 is connected to the second layer 2 by a connection between materials. The second layer 2 exhibits good bondability with the conductor 4. A conductor 4 is, for example, a bonding wire, preferably a bonding wire made of gold or a bonding wire made of aluminum.

In a bonded system 364, the conductor 4 is bonded with the second layer 2 preferably by a ball bond 5, as indicated in FIG. 2, or a wedge bond 5, as indicated in FIG. 3, by a bond between materials.

FIGS. 4 to 6 exemplarily show several embodiments of a bonded system 364. However, the embodiments are not limited to the examples shown. Thus, particularly other types of partial coverings of a support surface 7 or different geometric configurations of a support 3 are also conceivable. Likewise, only one or two bonds with a conductor 4 are exemplarily shown. However, it is explicitly noted that also a plurality of bonds with a plurality of conductors 4 are possible.

FIG. 4 shows a cuboid-shaped support 3. One of the six planar surfaces of the support 3 serves as the support surface 7 and is partially covered with a strip-shaped metallization 6 shown as a dotted surface. The metallization 6 is connected to a conductor 4 at a first conductor end 8 (not shown in FIGS. 4 to 6 for clarity but shown in FIGS. 2 and 3) by a connection 5 between materials. In this case and also in FIGS. 2 to 6, the conductor is represented with an arbitrary length as indicated by the curved outer edge. The second end of the conductor is not shown. Those skilled in the art may also design the metallization as conducting paths on a support 3 analogously to FIG. 4.

FIG. 5 shows an example in which the upper surface 7 and the oppositely facing lower surface 7 of a cuboid-shaped support 3 are each covered entirely by a metallization 6. Each metallization 6 is connected to a conductor 4 at a first conductor end 8 by a connection 5 (as schematically depicted in FIGS. 2 and 3) between materials. This example may be used, for example, as a piezoelectric measuring element showing the piezoelectric transverse effect where piezoelectric charges may be picked off by means of the metallization 6 when a lateral force is applied to the cuboid-shaped support 3. When the support 3 is configured as a piezoelectric measuring element, the respective second ends 9 of the conductor (not shown) are usually connected to a charge amplifier or an impedance converter (both not shown) in an electrically conductive manner. Those skilled in the art may also provide an edge region of the upper and lower surfaces without metallization in order to avoid lateral bonding (not shown).

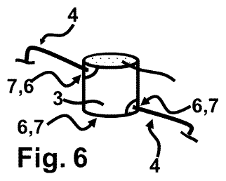

FIG. 6 is an example in which the upper surface 7 and the oppositely facing lower surface 7 of a disc-shaped support 3 are each entirely covered by a metallization 6. The lateral surface is defined by two partial areas comprising a metallization 6 that are connected in an electrically conductive manner to a metallization of the upper and the lower surface, respectively, each of which forms a metallization 6 in this example, i.e., a total of 2 metallizations 6 that are electrically separated from each other. This example shows that a metallization 6 may also be configured to extend beyond the edges of a support 3, i.e., may be adapted to the topography of the support 3. Each metallization 6 is connected to the partial area on the lateral surface by a conductor 4 at a first conductor end 8 (as schematically depicted in FIGS. 2 and 3) by means of a connection 5 between materials. This example may be used, for example, as a piezoelectric measuring element showing the piezoelectric longitudinal effect where piezoelectric charges may be picked off by means of the metallization 6 when a force is applied along the vertical axis of symmetry of the cylindrical support 3. When the support is configured as a piezoelectric measuring element, the respective second ends 9 of the conductor (not shown) are usually connected to a charge amplifier or an impedance converter (both not shown) in an electrically conductive manner.

A system 34 is manufactured, for example, by providing a support 3 in a first step. The support 3 defines a support surface 7 to which a first layer 1 is applied in a second step. Generally, the first layer 1 is applied to the support surface 7 by sputtering, also known as cold cathode sputtering, or by vapor deposition. Shaping of the first layer 1 is achieved by masking and/or laser structuring of the support surface 7. In a third step, a second layer 2 is applied onto the first layer 1. Generally, the second layer 2 is also applied to the support surface 7 by sputtering or vapor deposition. Shaping of the second layer 2 is performed by masking and/or laser structuring of the support surface 7. The second layer may also be applied by an electroplating process. Laser structuring after the first layer 1 and second layer 2 have been applied would also be possible.

Unless otherwise stated, all information provided on physical parameters and properties refers to a temperature of 20° C. and normal ambient pressure (normal pressure) of 101.3 kPa (kilopascals).

Embodiments comprising a combination of the features of embodiments described herein are also explicitly encompassed by this document.

### LIST OF REFERENCE NUMERALS

1 First layer
2 Second layer
3 Support
4 Conductor, bonding wire
5 Connection, bond, connection between materials,
6 ball-bond, wedge-bond
6 Metallization
7 Support surface
8 First conductor end
9 Second conductor end
12 Contact plane
13 Contact plane
36 System
364 Bonded system
X First axis
Y Second axis
Z Third axis

What is claimed is:

1. A system comprising:
an oxide ceramic support that defines a support surface;
at least one metallization attached to at least a portion of the support surface of the support;
wherein the metallization includes at least a first layer and a second layer;
wherein the first layer is arranged between the support surface and the second layer;
wherein the second layer is made of at least 90% by wt. of a precious metal;
wherein the first layer is made of transition metals and/or metals and/or semi-metals;
wherein the first layer has an ultrasonic damping effect; and
wherein the first layer exhibits a mechanical loss coefficient of at least 10⁻⁴ and a layer thickness of 500 nm to 4 μm.

2. The system according to claim 1, wherein the first layer exhibits a mechanical loss coefficient of at least 10⁻⁴ for mechanical vibrations with a frequency between 20 KHz and 200 kHz.

3. The system according to claim 1, wherein the first layer exhibits a modulus of elasticity between 60 GPa and 130 GPa.

4. The system according to claim 1, wherein the first layer consists of a metal or an alloy which has a negative standard enthalpy of formation of the oxide of the metal or alloy concerned in the temperature range up to 350° C.; and wherein the first layer is made of bronze or a copper alloy.

5. The system according to claim 1, wherein the support is an oxide ceramic exhibiting a modulus of elasticity between 90 GPa and 110 GPa and a coefficient of linear thermal expansion between α=12·10⁻⁶ K⁻¹ and α=18·10⁻⁶ K⁻¹.

6. The system according to claim 1, wherein the first layer is configured as an adhesion promoting layer for the support surface and is connected to the support surface by a connection between materials; and
wherein the first layer exhibits a coefficient of thermal expansion between α=5·10⁻⁶ K⁻¹ and α=18·10⁻⁶ K⁻¹.

7. The system according to claim 1, wherein the second layer has a layer thickness of between 20 nm and 300 nm.

8. The system according to claim 1, wherein the second layer has a high mechanical resistance and is made of platinum or a platinum alloy with a platinum content of at least 90% by weight.

9. The system according to claim 1, wherein the first layer is a bronze alloy comprising copper, tin and nickel;
wherein the first layer comprises 84.5% by wt. to 87.5% by wt. of copper, 11% by wt. to 13% by wt. of tin, 1.5% by wt. to 2.5% by wt. of nickel; and
wherein the first layer comprises a maximum of 16% by wt. of elements other than copper, tin and nickel.

10. The system according to claim 9, wherein the modulus of elasticity of the first layer differs from the modulus of elasticity of the support by not more than 20%; and
wherein the modulus of elasticity of the first layer differs from the modulus of elasticity of the support by not more than 20%.

11. The system according to claim 10, wherein the coefficient of thermal expansion of the first layer differs from the coefficient of thermal expansion of the support by not more than 20%.

12. The system according to claim 11, wherein the support is a piezoelectric material.

13. The system according to claim 1, wherein the second layer exhibits a modulus of elasticity greater than 150 GPa.

14. The system according to claim 1, wherein the second layer has a high scratch resistance that exhibits a Mohs hardness greater than 3.

15. A bonded system comprising:
at least one conductor;
a support electrically connected to the conductor by at least one metallization, wherein the at least one metallization includes at least a first layer and a second layer, wherein the first layer is disposed between the support and the second layer, wherein the second layer is made of at least 90% by wt. of a precious metal, wherein the first layer is made of transition metals and/or metals and/or semi-metals, wherein the first layer has an ultrasonic damping effect, wherein the first layer exhibits a mechanical loss coefficient of at least 10-4 and a layer thickness of 500 nm to 4 μm;
wherein the conductor defines a first conductor end and a second conductor end;
wherein the first conductor end is bonded with the second layer;
wherein the second layer has good bondability with the conductor, which is a bonding wire made of gold or a bonding wire made of aluminum.

16. The system according to claim 1, wherein the first layer exhibits a mechanical loss coefficient of at least 10⁻⁴ for mechanical vibrations with a frequency between 40 KHz and 160 KHz.

17. The system according to claim 1, wherein the first layer exhibits a modulus of elasticity between 80 GPa and 100 GPa.

18. The system according to claim 9, wherein the modulus of elasticity of the first layer differs from the modulus of elasticity of the support by not more than; wherein the modulus of elasticity of the first layer differs from the modulus of elasticity of the support by not more than 10%.

19. The system according to claim 10, wherein the coefficient of thermal expansion of the first layer differs from the coefficient of thermal expansion of the support by not more than 10%.

20. The system according to claim 6, wherein the connection between materials is effected by a chemical bond between the adhesion promoting first layer and the support surface.
